(19) United States
(12) Patent Application Publication
(10) Pub. No.: US 2019/0245022 A1
(43) Pub. Date: Aug. 8, 2019

(54) OLED DISPLAY PANEL

(71) Applicant: Shenzhen China Star Optoelectronics Semiconductor Display Technology Co., Ltd., Shenzhen (CN)

(72) Inventor: Xingyu ZHOU, Shenzhen (CN)

(21) Appl. No.: 15/767,353

(22) PCT Filed: Mar. 9, 2018
(86) PCT No.: PCT/CN2018/078491

§ 371 Date: Apr. 11, 2018

(30) Foreign Application Priority Data
Feb. 8, 2018 (CN) 201810126817.1

(51) Int. Cl. H01L 27/32; H01L 51/52; H01L 51/56

(52) U.S. Cl. CPC H01L 27/3272; H01L 27/322; H01L 27/3258; H01L 27/1248; H01L 51/5221; H01L 51/56; H01L 2251/5315; H01L 51/5206

(57) ABSTRACT

The present disclosure provides an organic light-emitting diode (OLED) display panel including an array substrate and a color filter cover plate. The array substrate includes a thin film transistor layer and an OLED layer. The color filter cover plate includes a color resist layer. The color resist layer includes a first color resist region and a second color resist region. The first color resist region corresponds to the OLED layer, and the second color resist region corresponds to the thin film transistor layer. The second color resist region includes two or three color resist blocks that are stacked on each other and have different colors.

### FIELD OF INVENTION

The present disclosure relates to the field of flat panel display technology, and more particularly to an organic light-emitting diode (OLED) display panel.

### BACKGROUND

Among different types of flat panels, organic light-emitting diode (OLED) displays have outstanding properties, including being light weight, thin, self-illuminating, short response times, wide viewing angles, a wide color gamut, high brightness, and low power consumption. Thus, succeeding liquid crystal displays (LCDs), OLED displays have gradually become a third generation display technology. In comparing OLED displays and LCDs, OLED displays save more energy, are thinner, and have wider viewing angles, to which the LCDs cannot compete. Nevertheless, users are getting increasingly unsatisfied with resolution of displayed images, and production of OLED displays with high quality and high resolution still face a lot of challenges.

FIG. 1 shows a cross-sectional view of a structure of an OLED display panel according to the prior art. The conventional OLED display panel includes an array substrate and a color filter cover plate. The array substrate includes a first substrate 101, a thin film transistor layer 102, and an OLED layer 103. The color filter cover plate includes a second substrate 107 and a color resist layer. The color resist layer includes a first color resist region and a second color resist region. The first color resist region corresponds to the OLED layer, and the second color resist region corresponds to the thin film transistor layer. The second color resist region includes one of a red color resist block, a green color resist block, and a blue color resist block. Light passes through the second substrate and the second color resist region, and enter the thin film transistor layer. However, the thin film transistor layer is made of an oxide semiconductor material. Once the thin film transistor layer is illuminated by the light, the thin film transistor layer would become unstable, making display of OLED display panels abnormal.

### SUMMARY OF DISCLOSURE

The present disclosure provides an organic light-emitting diode (OLED) display panel to solve the problem encountered by the prior art, where the thin film transistor layer of the conventional OLED display panel is influenced due to light illumination.

To solve the aforementioned problem, the present disclosure provides the following technical schemes.

The present disclosure provides an organic light-emitting diode (OLED) display panel, comprising:

an array substrate including a first substrate, a thin film transistor layer, and an OLED layer, wherein the thin film transistor layer is disposed on the first substrate, and the OLED layer is disposed on the thin film transistor layer; and

a color filter cover plate disposed facing the array substrate and including a second substrate and a color resist layer, wherein the color resist layer is disposed on the second substrate;

wherein the color resist layer includes:
a first color resist region corresponding to the OLED layer; and
a second color resist region corresponding to the thin film transistor layer, wherein the second color resist region includes a first color resist and a second color resist, and the second color resist is disposed on the first color resist;

wherein the second color resist region further includes a third color resist disposed on the second color resist; the third color resist is selected from one of a red color resist block, a green color resist block, and a blue color resist block; and the first color resist, the second color resist, and the third color resist are of different colors; and

wherein a laminated layer including the first color resist, the second color resist, and the third color resist is configured to block light from illuminating the thin film transistor layer.

In accordance with one preferred embodiment of the present disclosure, the first color resist is selected from one of a red color resist block, a green color resist block, and a blue color resist block; and the second color resist is selected from another of a red color resist block, a green color resist block, and a blue color resist block and is different from the first color resist.

In accordance with one preferred embodiment of the present disclosure, the second color resist region further includes a third color resist disposed on the second color resist; the third color resist is selected from one of a red color resist block, a green color resist block, and a blue color resist block; and the first color resist, the second color resist, and the third color resist are of different colors.

In accordance with one preferred embodiment of the present disclosure, a laminated layer including the first color resist, the second color resist, and the third color resist is configured to block light from illuminating the thin film transistor layer.

In accordance with one preferred embodiment of the present disclosure, the OLED display panel further comprises:

a passivation layer and a planarization layer, wherein the passivation layer and the planarization layer are disposed between the OLED layer and the thin film transistor layer.

In accordance with one preferred embodiment of the present disclosure, the OLED display panel further comprises:

an anode layer disposed on the thin film transistor layer, wherein the anode layer includes at least two anodes arranged in an array, and the anode layer is configured to provide a plurality of holes to receive a plurality of electrons; and

a cathode layer disposed on the OLED layer, wherein the cathode layer is configured to provide the electrons.

In accordance with one preferred embodiment of the present disclosure, the anode layer, the OLED layer, and the cathode layer collectively constitute an OLED device, and the OLED device is a top-emitting type OLED device.

In accordance with one preferred embodiment of the present disclosure, the OLED device is a white light OLED device emitting white light.

In accordance with one preferred embodiment of the present disclosure, the OLED layer includes:

a first common layer disposed on the anode layer, wherein the first common layer is configured for injection and transmission of the holes;

a light-emitting layer disposed on the first common layer; and

a second common layer disposed on the first common layer, wherein the second common layer is configured for injection and transmission of the electrons.

In accordance with one preferred embodiment of the present disclosure, the first common layer includes a hole injection layer and a hole transmission layer, and the second common layer includes an electron injection layer and an electron transmission layer.

In accordance with one preferred embodiment of the present disclosure, the second color resist region further includes a light-shielding block made of a light-shielding material.

Additionally, the present disclosure provides an organic light-emitting diode (OLED) display panel, comprising:

an array substrate including a first substrate, a thin film transistor layer, and an OLED layer, wherein the thin film transistor layer is disposed on the first substrate, and the OLED layer is disposed on the thin film transistor layer; and

a color filter cover plate disposed facing the array substrate and including a second substrate and a color resist layer, wherein the color resist layer is disposed on the second substrate;

wherein the color resist layer includes:
a first color resist region disposed corresponding to the OLED layer; and
a second color resist region corresponding to the thin film transistor layer, wherein the second color resist region includes a first color resist and a second color resist, and the second color resist is disposed on the first color resist.

In accordance with one preferred embodiment of the present disclosure, the first color resist is selected from one of a red color resist block, a green color resist block, and a blue color resist block; and the second color resist is selected from another of a red color resist block, a green color resist block, and a blue color resist block and is different from the first color resist.

In accordance with one preferred embodiment of the present disclosure, the OLED display panel further comprises:

a passivation layer and a planarization layer, wherein the passivation layer and the planarization layer are disposed between the OLED layer and the thin film transistor layer.

In accordance with one preferred embodiment of the present disclosure, the OLED display panel further comprises:

an anode layer disposed on the thin film transistor layer, wherein the anode layer includes at least two anodes arranged in an array, and the anode layer is configured to provide a plurality of holes to receive a plurality of electrons; and

a cathode layer disposed on the OLED layer, wherein the cathode layer is configured to provide the electrons.

In accordance with one preferred embodiment of the present disclosure, the anode layer, the OLED layer, and the cathode layer collectively constitute an OLED device, and the OLED device is a top-emitting type OLED device.

In accordance with one preferred embodiment of the present disclosure, the OLED device is a white light OLED device emitting white light.

In accordance with one preferred embodiment of the present disclosure, the OLED layer includes:

a first common layer disposed on the anode layer, wherein the first common layer is configured for injection and transmission of the holes;

a light-emitting layer disposed on the first common layer; and

a second common layer disposed on the first common layer, wherein the second common layer is configured for injection and transmission of the electrons.

In accordance with one preferred embodiment of the present disclosure, the first common layer includes a hole injection layer and a hole transmission layer, and the second common layer includes an electron injection layer and an electron transmission layer.

In accordance with one preferred embodiment of the present disclosure, the second color resist region further includes a light-shielding block made of a light-shielding material.

The present disclosure is characterized in formation of two or three color resist blocks having different colors in the second color resist region corresponding to the thin film transistor layer, such that light passing through the second color resist region would not illuminate the thin film transistor layer, and thus stability of the thin film transistor layer is increased.

### BRIEF DESCRIPTION OF DRAWINGS

To explain in detail the technical schemes of the embodiments or existing techniques, drawings that are used to illustrate the embodiments or existing techniques are provided. The illustrated embodiments are just a part of those of the present disclosure. It is easy for any person having ordinary skill in the art to obtain other drawings without labor for inventiveness.

FIG. 1 is a schematic diagram showing a cross-sectional view of a structure of an OLED display panel according to the prior art.

FIG. 2 is a schematic diagram showing a cross-sectional view of a structure of an OLED display panel according to a first preferred embodiment of the present disclosure.

FIG. 3 is a schematic diagram showing a cross-sectional view of a structure of an OLED display panel according to a second preferred embodiment of the present disclosure.

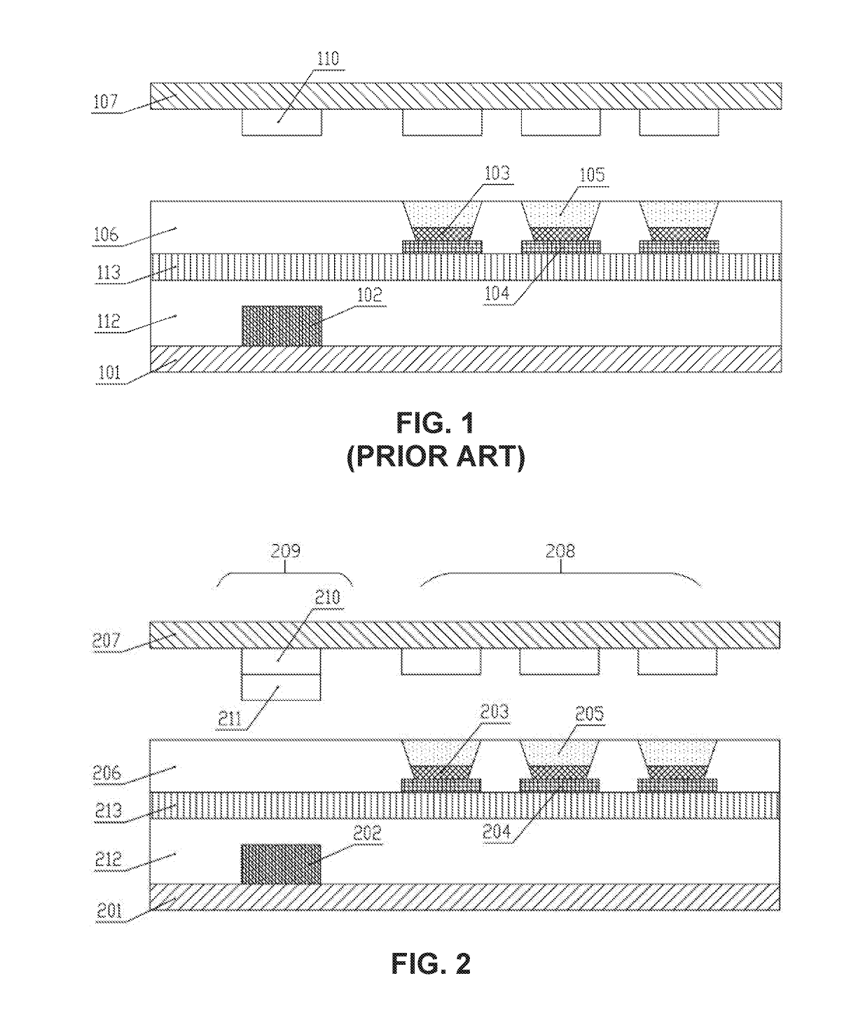

### DETAILED DESCRIPTION

The following embodiments refer to the accompanying drawings for exemplifying specific implementable embodiments of the present disclosure. Moreover, directional terms described by the present disclosure, such as upper, lower, front, back, left, right, inner, outer, side, etc., are only directions by referring to the accompanying drawings, and thus the used directional terms are used to describe and understand the present disclosure, but the present disclosure is not limited thereto. In the drawings, the same reference symbol represents the same or similar components.

FIG. 2 is a schematic diagram showing a cross-sectional view of a structure of an OLED display panel according to a first preferred embodiment of the present disclosure. The OLED display panel includes an array substrate and a color filter cover plate.

The array substrate includes a first substrate 201, a thin film transistor layer 202, and an OLED layer 203. The thin film transistor layer 202 is disposed on the first substrate 201, and the OLED layer 203 is disposed on the thin film transistor layer 202.

The first substrate 201 can be a glass substrate, a silicon substrate, or a resin substrate.

The thin film transistor layer has an etching stop layer (ESL) structure, a back channel etching (BCE) structure, or a top-gate structure, but is not limited thereto. The present embodiment uses the back channel etching (BCE) structure as an example for explanation of the subject invention. The thin film transistor layer includes a first metal layer, a gate insulation layer, an active layer, an ohmic contact layer, a second metal layer, and a passivation layer.

The first metal layer is deposited on the first substrate 201. The first metal layer can be made of molybdenum, aluminum, aluminum-nickel alloy, molybdenum-tungsten alloy, chromium, or copper, or can have a multi-layer structure including these materials. A first mask process is performed for the first metal layer to form a plurality of gates and a plurality of gate lines of thin film transistors. The gate insulation layer covers the first metal layer and the first substrate 201. In the present embodiment, the gate insulation layer is made of silicon nitride, silicon oxide, or silicon oxynitride. The active layer is formed on the gate insulation layer. The active layer is made of an oxide semiconductor material, such as indium gallium zinc oxide (IGZO), indium tin zinc oxide (ITZO), indium gallium zinc tin oxide (IGZTO), etc. The active layer is composed of a plurality of carbon nanotubes.

The ohmic contact layer is formed on the active layer. The ohmic contact layer is made from an n⁺ carbon nanotube solution doped with electrons. The ohmic contact layer is also named a doping layer because the active layer is made of an n-type semiconductor material. If this material directly contacts a metal film, a Schottky barrier would be generated, which may possibly adversely influence electric properties of thin film transistor devices, and make light emission of display panels abnormal. Therefore, it is required to deposit an ohmic contact layer on the active layer first before the second metal layer is deposited on the active layer, so as to prevent the second metal layer from directly contacting the active layer.

The second metal layer is deposited on the active layer. Both the first metal layer and the second metal layer can be formed using a sputtering technique. In the present embodiment, the second metal layer can be made of a material different from or the same as a material of the first metal layer. The materials used to form the first and second metal layers include molybdenum, aluminum, aluminum-nickel alloy, molybdenum-tungsten alloy, chromium, or copper. Alternatively, the first and second metal layers can have a multi-layer structure including these materials. A second mask process is performed for the second metal layer to form a plurality of sources and a plurality of drains of thin film transistors.

The passivation layer 212 is formed on the second metal layer. The passivation layer is generally made of silicon nitride. A planarization layer 213 is formed on the passivation layer to improve planarity of the deposited layers.

The OLED layer 203 is formed on the planarization layer. An anode layer 204, the OLED layer 203, and a cathode layer 205 collectively constitute an OLED device. In the present embodiment, the OLED device is a top-emitting type OLED device. The OLED device is a white light OLED device emitting white light.

The anode layer 204 is formed on the planarization layer 213. The anode layer 204 includes at least two anodes arranged in an array. The anode layer 204 is configured to provide a plurality of holes to receive a plurality of electrons. The anode layer 204 is a light-blocking layer that is opaque.

The OLED layer 203 is formed on the anode layer 204. The OLED layer 203 is divided by a pixel defining layer 206 into a plurality of portions. The OLED layer 203 includes a first common layer, a light-emitting layer, and a second common layer. The first common layer is configured for injection and transmission of the holes. The first common layer includes a hole injection layer and a hole transmission layer. Thus, the first common layer can be alternatively named a hole transport function layer. The second common layer is formed on the first common layer. The second common layer is configured for injection and transmission of the electrons. The second common layer includes an electron injection layer and an electron transmission layer. Thus, the second common layer can be alternatively named an electron transport function layer. The light-emitting layer is disposed between the first common layer and the second common layer. The light-emitting layer is made of an organic semiconductor material having a special band gap structure, and can emit photons of certain wavelength after receiving electrons moved from the anode electrodes. These photons enter our eyes to form colors that we see.

The cathode layer 205 is formed on the OLED layer 203. The cathode layer 205 is configured to provide the electrons. According to the present disclosure, the cathode layer 205 is made of a transparent material, such that light generated by the light-emitting layer can pass through the cathode layer 205 and emit outward.

The color filter cover plate is disposed facing the array substrate. The color filter cover plate includes a second substrate 207 and a color resist layer.

The second substrate 207 and the first substrate 201 of the array substrate are of the same material, both functioning as a base plate.

The color resist layer is disposed on the second substrate 207. The color resist layer includes a first color resist region 208 and a second color resist region 209. The first color resist region 208 corresponds to the OLED layer 203. As shown in FIG. 2, different portions of the OLED layer 203 correspond to different color resist blocks. The first color resist region 208 includes at least one of a red color resist block, a green color resist block, and a blue color resist block.

The second color resist region 209 corresponds to the thin film transistor layer 202. The second color resist region 209 includes a first color resist 210 and a second color resist 211, and the second color resist 211 is formed on the first color resist 210. The first color resist 210 is selected from one of a red color resist block, a green color resist block, and a blue color resist block. The second color resist 211 is selected from another of a red color resist block, a green color resist block, and a blue color resist block and is different from the first color resist 210. As shown in FIG. 2, for ease of explanation, the first color resist 210 is a red color resist block, and the second color resist 211 is a blue color resist block.

Please further refer to FIG. 2. For the external light passing through the second substrate 207 and the light generated by the light-emitting layer of the OLED layer 203 and reflected or refracted inside the panel, the light will enter the thin film transistor layer 202. As described above for the conventional OLED display panels, once the thin film transistor layer 202 is illuminated by the light, the oxide semiconductor material in the thin film transistor layer would become unstable, making display of OLED display panels abnormal. The present disclosure solves this problem. According to this embodiment of the present disclosure, as the incident light passes through the first color resist (i.e., red color resist block) 210, the incident light is filtered to be red light. And, as the red light further passes through the second color resist (i.e., blue color resist block) 211, there will be no colored light emitting from the second color resist (i.e., blue color resist block). In other words, according to the present disclosure, the subject invention solves the red light leaking problem in the non-display region of the display panel. To achieve this effect, the first color resist 210 has a thickness that is the same as or approximate to a thickness of the second color resist 211.

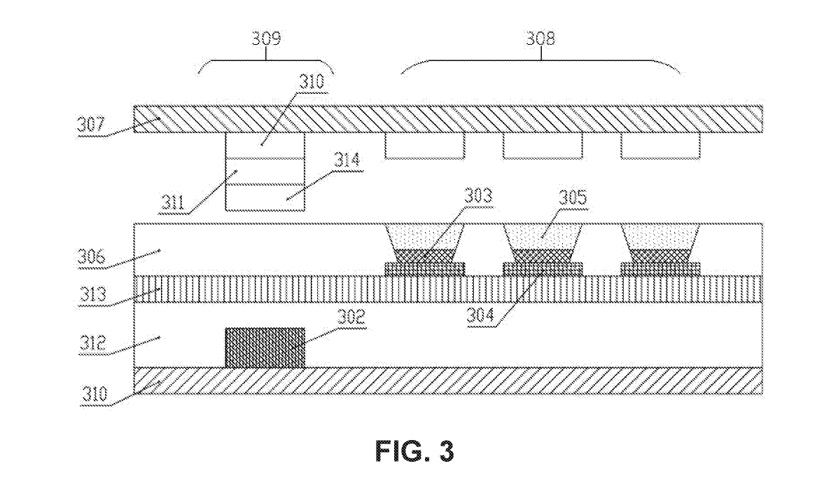

FIG. 3 is a schematic diagram showing a cross-sectional view of a structure of an OLED display panel according to a second preferred embodiment of the present disclosure. The second color resist region 309 further includes a third color resist 314 formed on the second color resist 311. The third color resist 314 is selected from one of a red color resist block, a green color resist block, and a blue color resist block. In addition, the first color resist 310, the second color resist 311, and the third color resist 314 are of different colors. In the present embodiment, for ease of explanation, the first color resist 310 is a red color resist block, the second color resist 311 is a blue color resist block, and the third color resist 314 is a green color resist block.

As shown in FIG. 3, this second preferred embodiment differs from the above first preferred embodiment in that a third color resist 314, which is different from the first color resist 310 and the second color resist 311, is additionally formed on the second color resist 311, to prevent some of light from passing through the color resist blocks as the light pass through the first color resist 310 and the second color resist 311. Therefore, formation of the third color resist 314 completely protects the thin film transistor layer 302 from light illumination. The thickness of the color filter cover pate in the second preferred embodiment would be thicker than that of the color filter cover pate in the first preferred embodiment.

The second color resist region further includes a light-shielding block. That is, the third color resist is replaced with a black light-shielding block. The light-shielding block can be made of a light-shielding material, such as a black matrix.

The present disclosure provides an OLED display panel including an array substrate and a color filter cover plate. The array substrate includes a first substrate, a thin film transistor layer, and an OLED layer. The color filter cover plate includes a second substrate and a color resist layer. The color resist layer includes a first color resist region disposed corresponding to the OLED layer, and a second color resist region corresponding to the thin film transistor layer. The second color resist region includes two or three color resist blocks that are stacked on each other and have different colors. The present disclosure is characterized in formation of two or three color resist blocks having different colors in the second color resist region corresponding to the thin film transistor layer, such that the light passing through the second color resist region would not illuminate the thin film transistor layer, and thus stability of the thin film transistor layer is increased.

While the present disclosure has been described with the aforementioned preferred embodiments, it is preferable that the above embodiments should not be construed as limiting of the present disclosure. Anyone having ordinary skill in the art can make a variety of modifications and variations without departing from the spirit and scope of the present disclosure as defined by the following claims.

What is claimed is:

1. An organic light-emitting diode (OLED) display panel, comprising:
an array substrate including a first substrate, a thin film transistor layer, and an OLED layer, wherein the thin film transistor layer is disposed on the first substrate, and the OLED layer is disposed on the thin film transistor layer; and
a color filter cover plate disposed facing the array substrate and including a second substrate and a color resist layer, wherein the color resist layer is disposed on the second substrate;
wherein the color resist layer includes:
a first color resist region corresponding to the OLED layer; and
a second color resist region corresponding to the thin film transistor layer, wherein the second color resist region includes a first color resist and a second color resist, and the second color resist is disposed on the first color resist;
wherein the second color resist region further includes a third color resist disposed on the second color resist; the third color resist is selected from one of a red color resist block, a green color resist block, and a blue color resist block; and the first color resist, the second color resist, and the third color resist are of different colors; and
wherein a laminated layer including the first color resist, the second color resist, and the third color resist is configured to block light from illuminating the thin film transistor layer.

2. The OLED display panel according to claim 1, wherein the first color resist is selected from one of a red color resist block, a green color resist block, and a blue color resist block; and the second color resist is selected from another of a red color resist block, a green color resist block, and a blue color resist block and is different from the first color resist.

3. The OLED display panel according to claim 1, wherein the OLED display panel further comprises:
a passivation layer and a planarization layer, wherein the passivation layer and the planarization layer are disposed between the OLED layer and the thin film transistor layer.

4. The OLED display panel according to claim 1, wherein the OLED display panel further comprises:
an anode layer disposed on the thin film transistor layer, wherein the anode layer includes at least two anodes arranged in an array, and the anode layer is configured to provide a plurality of holes to receive a plurality of electrons; and
a cathode layer disposed on the OLED layer, wherein the cathode layer is configured to provide the electrons.

5. The OLED display panel according to claim 4, wherein the anode layer, the OLED layer, and the cathode layer collectively constitute an OLED device, and the OLED device is a top-emitting type OLED device.

6. The OLED display panel according to claim 5, wherein the OLED device is a white light OLED device emitting white light.

7. The OLED display panel according to claim 5, wherein the OLED layer includes:
a first common layer disposed on the anode layer, wherein the first common layer is configured for injection and transmission of the holes;
a light-emitting layer disposed on the first common layer; and
a second common layer disposed on the first common layer, wherein the second common layer is configured for injection and transmission of the electrons.

8. The OLED display panel according to claim 7, wherein the first common layer includes a hole injection layer and a hole transmission layer, and the second common layer includes an electron injection layer and an electron transmission layer.

9. The OLED display panel according to claim 1, wherein the second color resist region further includes a light-shielding block made of a light-shielding material.

10. An organic light-emitting diode (OLED) display panel, comprising:
an array substrate including a first substrate, a thin film transistor layer, and an OLED layer, wherein the thin film transistor layer is disposed on the first substrate, and the OLED layer is disposed on the thin film transistor layer; and
a color filter cover plate disposed facing the array substrate and including a second substrate and a color resist layer, wherein the color resist layer is disposed on the second substrate;
wherein the color resist layer includes:
a first color resist region disposed corresponding to the OLED layer; and
a second color resist region corresponding to the thin film transistor layer, wherein the second color resist region includes a first color resist and a second color resist, and the second color resist is disposed on the first color resist.

11. The OLED display panel according to claim 10, wherein the first color resist is selected from one of a red color resist block, a green color resist block, and a blue color resist block; and the second color resist is selected from another of a red color resist block, a green color resist block, and a blue color resist block and is different from the first color resist.

12. The OLED display panel according to claim 10, wherein the OLED display panel further comprises:
a passivation layer and a planarization layer, wherein the passivation layer and the planarization layer are disposed between the OLED layer and the thin film transistor layer.

13. The OLED display panel according to claim 10, wherein the OLED display panel further comprises:
an anode layer disposed on the thin film transistor layer, wherein the anode layer includes at least two anodes arranged in an array, and the anode layer is configured to provide a plurality of holes to receive a plurality of electrons; and
a cathode layer disposed on the OLED layer, wherein the cathode layer is configured to provide the electrons.

14. The OLED display panel according to claim 13, wherein the anode layer, the OLED layer, and the cathode layer collectively constitute an OLED device, and the OLED device is a top-emitting type OLED device.

15. The OLED display panel according to claim 14, wherein the OLED device is a white light OLED device emitting white light.

16. The OLED display panel according to claim 14, wherein the OLED layer includes:
a first common layer disposed on the anode layer, wherein the first common layer is configured for injection and transmission of the holes;
a light-emitting layer disposed on the first common layer; and
a second common layer disposed on the first common layer, wherein the second common layer is configured for injection and transmission of the electrons.

17. The OLED display panel according to claim 16, wherein the first common layer includes a hole injection layer and a hole transmission layer, and the second common layer includes an electron injection layer and an electron transmission layer.

18. The OLED display panel according to claim 10, wherein the second color resist region further includes a light-shielding block made of a light-shielding material.
